(19) United States
(12) Patent Application Publication
(10) Pub. No.: US 2014/0246666 A1
(43) Pub. Date: Sep. 4, 2014

(54) SEMICONDUCTOR DEVICE AND METHOD FOR MANUFACTURING THE SAME

(71) Applicant: KABUSHIKI KAISHA TOSHIBA, Tokyo (JP)

(72) Inventors: Tetsu MOROOKA, Kanagawa-ken (JP); Tatsuya OHGURO, Kanagawa-ken (JP); Hisayo MOMOSE, Kanagawa-ken (JP); Kazuya FUKASE, Tokyo (JP)

(73) Assignees: KABUSHIKI KAISHA TOSHIBA, Tokyo (JP); EPAS

(21) Appl. No.: 13/935,195

(22) Filed: Jul. 3, 2013

(30) Foreign Application Priority Data
Mar. 4, 2013 (JP) 2013-041994

(51) Int. Cl. H01L 29/786

(52) U.S. Cl. CPC H01L 29/7869
USPC 257/43; 438/104

(57) ABSTRACT

In general, according to one embodiment, a semiconductor device includes a first electrode, an oxide semiconductor film, an insulating film, a second electrode, a third electrode. The oxide semiconductor film is configured together with a first region, a second region, a third region, a fourth region, and a fifth region in one direction. The insulating film is provided between the first electrode and the oxide semiconductor film. The second electrode is provided on the second region and contacts the second region with an entire upper face of the second region as a contact face. The third electrode is provided on the fourth region and contacts the fourth region with an entire upper face of the fourth region as a contact face. The oxygen concentrations in the second region and in the fourth region are less than the oxygen concentration in the third region.

### CROSS-REFERENCE TO RELATED APPLICATIONS

This application is based upon and claims the benefit of priority from Japanese Patent Application No. 2013-041994, filed on Mar. 4, 2013; the entire contents of which are incorporated herein by reference.

### FIELD

Embodiments described herein relate generally to a semiconductor device and method for manufacturing the same.

### BACKGROUND

Semiconductor devices, such as a thin film transistor (TFT), are widely used in image display devices including liquid crystal display devices, organic electro luminescence (EL) display devices, and the like. In recent years, semiconductor devices are being developed that use an oxide semiconductor in which In—Ga—Zn—O or the like is used as an active layer semiconductor film. Oxide semiconductors can be formed easily even at cold temperatures and have high mobility of at least 10 cm²/Vs. More improvement is desired in the characteristics of semiconductor devices that use oxide semiconductors.

### BRIEF DESCRIPTION OF THE DRAWINGS

FIG. 1A and FIG. 1B are schematic cross-sectional views illustrating a semiconductor device according to a first embodiment;

FIG. 2A to FIG. 4B are schematic cross-sectional views showing one example of a method for manufacturing the semiconductor device;

FIG. 5A to FIG. 5D are schematic cross-sectional views illustrating the method (II) for manufacturing the semiconductor device;

FIG. 6A to FIG. 6B are schematic cross-sectional views illustrating the semiconductor device according to a second embodiment;

FIG. 7A to FIG. 8B are schematic cross-sectional views showing one example of the method for manufacturing the semiconductor device;

FIG. 9A and FIG. 9B are schematic cross-sectional views illustrating the method for manufacturing the semiconductor device according to a third embodiment;

FIG. 10A to FIG. 10C are schematic cross-sectional views showing one example of the method for manufacturing the semiconductor device;

FIG. 11 is a schematic cross-sectional view illustrating the semiconductor device according to a fourth embodiment; and

FIG. 12A to FIG. 13C are schematic cross-sectional views showing one example of the method for manufacturing the semiconductor device.

### DETAILED DESCRIPTION

In general, according to one embodiment, a semiconductor device includes a first electrode, an oxide semiconductor film, an insulating film, a second electrode, a third electrode. The oxide semiconductor film is configured together with a first region, a second region, a third region, a fourth region, and a fifth region in one direction. The insulating film is provided between the first electrode and the oxide semiconductor film. The second electrode is provided on the second region and contacts the second region with an entire upper face of the second region as a contact face. The third electrode is provided on the fourth region and contacts the fourth region with an entire upper face of the fourth region as a contact face. The oxygen concentrations in the second region and in the fourth region are less than the oxygen concentration in the third region.

Various embodiments will be described hereinafter with reference to the accompanying drawings.

In the following description, the same reference numeral is applied to the same member, and for members that have been described once, the description is omitted as appropriate.

### First Embodiment

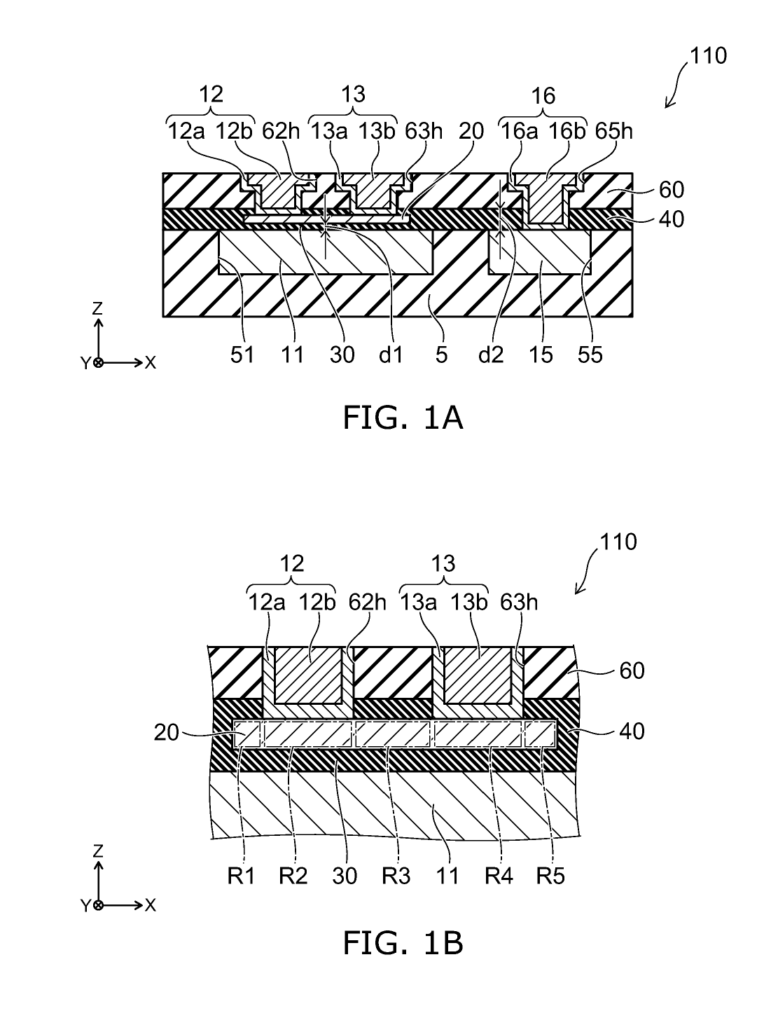

FIGS. 1A and 1B are schematic cross-sectional views illustrating examples of a semiconductor device according to the first embodiment.

FIG. 1A shows a schematic cross-sectional view of a semiconductor device 110 according to the first embodiment. FIG. 1B shows a partially enlarged schematic cross-sectional view of the semiconductor device 110 according to the first embodiment.

The semiconductor device 110, as shown in FIG. 1A, includes a first electrode 11, an oxide semiconductor film 20, a first insulating film 30, a second electrode 12, and a third electrode 13. The semiconductor device 110 is, for example, a TFT. The first electrode 11 is, for example, a gate electrode for the TFT. The second electrode 12 is, for example, a source electrode for the TFT. The third electrode 13 is, for example, a drain electrode for the TFT. The oxide semiconductor film 20 is, for example, an active layer where a channel for the TFT is formed. The first insulating film 30 is, for example, a portion of a gate insulating film for the TFT.

In the semiconductor device 110, the oxide semiconductor film 20 is provided between the first electrode 11 and the second electrode 12 and the third electrode 13. Note that the first electrode 11, the second electrode 12, and the third electrode 13 may be provided together with on the oxide semiconductor film 20.

The first electrode 11 is embedded in a groove 51 provided in an insulating portion 5. Copper (Cu) is used, for example, in the first electrode 11. The first electrode 11 is formed by, for example, a damascene method. In the embodiment, the first electrode 11 is embedded in the groove 51 of the insulating portion 5 by a damascene method using Cu. The first electrode 11 is provided in, for example, an island shape. The first electrode 11 may also be provided in a line shape.

The oxide semiconductor film 20 is provided on the first electrode 11. In the embodiment, a direction connecting the first electrode 11 and the oxide semiconductor film 20 is taken as the Z direction, one of directions orthogonal to the Z direction is taken as the X direction, and a direction orthogonal to both the Z direction and the X direction is taken as the Y direction.

The oxide semiconductor film 20 has a first region R1, a second region R2, a third region R3, a fourth region R4, and a fifth region R5 aligned in one direction. In the embodiment, the first region R1, the second region R2, the third region R3, the fourth region R4, and the fifth region R5 are aligned in this order in the X direction.

For example, indium (In)-gallium (Ga)-zinc (Zn)-oxygen (O) are provided in the oxide semiconductor film 20. An oxide including In or Zn other than In—Ga—Zn—O, such as In—O film, Zn—O film, In—Zn—O film, In—Ga—O film, Al—Zn—O film, In—Al—Zn—O film or the like may also be used in the oxide semiconductor film 20. A thickness of the oxide semiconductor film 20 is, for example, not less than 5 nanometers (nm) and not more than 100 nm.

The first insulating film 30 is provided between the first electrode 11 and the oxide semiconductor film 20. The first insulating film 30 is stacked, for example, on the first electrode 11. Silicon nitride (SiN), for example, is used as the first insulating film 30. Other than SiN, silicon oxide (SiO₂), silicon oxynitride (SiON), or even HfO₂ or HfSiON or the like may be used as the first insulating film 30. The use of Cu as the first electrode 11 and SiN as the first insulating film 30 effectively suppresses the diffusion of Cu into the oxide semiconductor film 20. The thickness of the first insulating film 30 is, for example, not less than 5 nm and not more than 500 nm.

The oxide semiconductor film 20 is covered by the second insulating film 40. The second insulating film 40 is provided so as to cover a face other than a face that contacts the first insulating film 30 of the oxide semiconductor film 20. The second insulating film 40 is also provided on an interconnection 15 arranged with the first electrode 11. The second insulating film 40 suppresses a foreign material from being introduced from an outer side of the oxide semiconductor film 20 to an inner side thereof. A foreign material includes substances including, for example, hydrogen.

The second insulating film 40 includes, for example, SiN. The second insulating film 40 may include one selected from the group consisting of aluminum oxide (Al₂O₃), titanium oxide (TiO₂), or tantalum oxide (Ta₂O₅). The material for the second insulating film 40 may be the same or different material as that of the first insulating film 30.

A protective film 60 is provided on the second insulating film 40. For the protective film 60, SiO₂, for example, is used. The protective film 60 is formed by, for example, a chemical vapor deposition (CVD) method. A thickness of the protective film 60 is, for example, not less than 100 nm and not more than 1000 nm. The second insulating film 40 and the protective film 60 function as interlayer insulating films provided on the first electrode 11 and the interconnection 15.

The second electrode 12 is provided on the second region R2 of the oxide semiconductor film 20. The second electrode 12 contacts the second region R2 with the entire upper face of the second region R2 as a contact face. The second electrode 12 is provided in a contact hole 62h provided in the protective film 60 and the second insulating film 40. The contact hole 62h is provided from a surface of the protective film 60 to the oxide semiconductor film 20. The second region R2 of the oxide semiconductor film 20 is a region where the bottom of the contact hole 62h and the oxide semiconductor film 20 overlap in the Z direction.

The second electrode 12 includes, for example, a first barrier film 12a and a first conductive portion 12b. The first barrier film 12a is formed along the inner wall of the contact hole 62h and on the bottom of the contact hole 62h. The first barrier film 12a contacts the second region R2 of the oxide semiconductor film 20 on the bottom of the contact hole 62h. The first conductive portion 12b is embedded in the contact hole 62h with the first barrier film 12a therebetween.

Tantalum nitride (TaN), for example, is used in the first barrier film 12a. Cu, for example, is used in the first conductive portion 12b. The first conductive portion 12b is formed in the contact hole 62h using, for example, a damascene method. The first barrier film 12a functions as a barrier film that suppresses the material of the first conductive portion 12b (for example, Cu), or substances included in the first conductive portion 12b (for example, substances including hydrogen), from being introduced to the oxide semiconductor film 20. Note that aluminum (Al) or the like may also be used instead of Cu for the second electrode 12.

The third electrode 13 is provided on the fourth region R4 of the oxide semiconductor film 20. The third electrode 13 contacts the fourth region R4 with the entire upper face of the fourth region R4 as the contact face. The third electrode 13 is provided in a contact hole 63h provided in the protective film 60 and the second insulating film 40. The contact hole 63h is provided from the surface of the protective film 60 to the oxide semiconductor film 20. The fourth region R4 of the oxide semiconductor film 20 is a region where the bottom of the contact hole 63h and the oxide semiconductor film 20 overlap in the Z direction.

The third electrode 13 includes, for example, a second barrier film 13a and a second conductive portion 13b. The second barrier film 13a is formed along the inner wall of the contact hole 63h and on the bottom of the contact hole 63h. The second barrier film 13a contacts the fourth region R4 of the oxide semiconductor film 20 on the bottom of the contact hole 63h. The second conductive portion 13b is embedded in the contact hole 63h with the second barrier film 13a therebetween.

TaN, for example, is used in the second barrier film 13a. Cu, for example, is used in the second conductive portion 13b. The second conductive portion 13b is formed in the contact hole 63h using, for example, a damascene method. The second barrier film 13a functions as a barrier film that suppresses the material of the second conductive portion 13b (for example, Cu), or substances included in the second conductive portion 13b (for example, substances including hydrogen), from being introduced to the oxide semiconductor film 20. Note that Al or the like may also be used instead of Cu for the third electrode 13.

The interconnection 15 is embedded in a groove 55 provided on the insulating portion 5. Cu is used, for example, in the interconnection 15. The interconnection 15 is formed by, for example, a damascene method. In the embodiment, the interconnection 15 is embedded in the groove 55 of the insulating portion 5 by a damascene method using Cu. The interconnection 15 conducts with, for example, the first electrode 11.

The second insulating film 40 and the protective film 60 are provided on the interconnection 15. A contact hole 65h is provided in the second insulating film 40 and protective film 60 on the interconnection 15. The contact hole 65h is provided from the surface of the protective film 60 to the interconnection 15.

An interconnection 16 is provided in the contact hole 65h. The interconnection 16 is a contact interconnection with the interconnection 15. The interconnection 16 includes, for example, a third barrier film 16a and a third conductive portion 16b. The third barrier film 16a is formed along the inner wall of the contact hole 65h and on the bottom of the contact hole 65h. The third barrier film 16a contacts the interconnection 15 on the bottom of the contact hole 65h. The third conductive portion 16b is embedded in the contact hole 65h with the third barrier film 16a therebetween.

TaN, for example, is used in the third barrier film 16a. Cu, for example, is used in the third conductive portion 16b. The third conductive portion 16b is formed in the contact hole 65h using, for example, a damascene method. Note that Al or the like may be used instead of Cu for the interconnection 16.

Here, a thickness d2 of the second insulating film 40 provided on the interconnection 15 is desired to be thicker than a thickness d1 of the first insulating film 30. The thickness d1 of the first insulating film 30 is, for example, about 30 nm. The thickness d2 of the second insulating film 40 is, for example, about 50 nm. The thickness d1 of the first insulating film 30 is desired to be thin in order to increase the drive capability and transconductance of the semiconductor device 110. Meanwhile, a certain degree of thickness is required in the thickness d2 of the second insulating film 40 for forming the interconnection 16 using a damascene method. In other words, formation of the groove becomes difficult when forming the interconnection 16 using a damascene method when the thickness d2 of the second insulating film 40 is as thin as the thickness d1 of the first insulating film 30. Therefore, the thickness d2 of the second insulating film 40 is desired to be thicker than the thickness d1 of the first insulating film 30.

As described above, the oxide semiconductor film 20 has the first region R1, the second region R2, the third region R3, the fourth region R4, and the fifth region R5 aligned in one direction. The second region R2 is a region where the bottom of the contact hole 62h and the oxide semiconductor film 20 overlap in the Z direction. The fourth region R4 is a region where the bottom of the contact hole 63h and the oxide semiconductor film 20 overlap in the Z direction. The first region R1 is a region farther to an outer side than the second region R2. The fifth region R5 is a region farther to the outer side than the fourth region R4. The third region R3 is a region between the second region R2 and the fourth region R4. The third region R3 is a region where the channel of the TFT is formed.

In the semiconductor device 110, an oxygen concentration in the second region R2 is less than an oxygen concentration in the third region R3. The oxygen concentration in the second region R2 may be less than each of an oxygen concentration in the first region R1, an oxygen concentration in the third region R3, and an oxygen concentration in the fifth region R5.

Further, in the semiconductor device 110, an oxygen concentration in the fourth region R4 is less than the oxygen concentration in the third region R3. The oxygen concentration in the fourth region R4 may be less than each of the oxygen concentration in the first region R1, the oxygen concentration in the third region R3, and the oxygen concentration in the fifth region R5. Each oxygen concentration here is the average oxygen concentration for the respective regions.

An oxygen concentration of the oxide semiconductor film 20 remarkably changes at the interface between the second region R2 and the third region R3. Further, the oxygen concentration of the oxide semiconductor film 20 remarkably changes at the interface between the fourth region R4 and the third region R3.

The oxygen concentration in the second region R2 is, for example, not less than 1 wt % and not more than 15 wt %. The oxygen concentration in the fourth region R4 is, for example, not less than 1 wt % and not more than 15 wt %. The oxygen concentration in the third region R3 is, for example, not less than 15 wt % and not more than 25 wt %. The oxygen concentration in the first region R1 is, for example, not less than 15 wt % and not more than 25 wt %. The oxygen concentration in the fifth region R5 is, for example, not less than 15 wt % and not more than 25 wt %.

In the semiconductor device 110, the oxygen concentration in a region (second region R2) where the oxide semiconductor film 20 contacts the second electrode 12, and the oxygen concentration in a region (fourth region R4) where the oxide semiconductor film 20 contacts the third electrode 13 are less than the oxygen concentration in a region (third region R3) where the channel is formed, and therefore, the electrical contact resistance is reduced between the oxide semiconductor film 20 and the second electrode 12 and between the oxide semiconductor film 20 and the third electrode 13.

In the semiconductor device 110, the oxygen concentration in the second region R2 that contacts the second electrode 12, and the oxygen concentration in the fourth region R4 that contacts the third electrode 13, are set so as to be low. As such, there is little effect on the oxygen concentration in the surrounding regions of the second region R2 (the first region R1 and the third region R3) and on the oxygen concentration in the surrounding regions of the fourth region R4 (the fifth region R5 and the third region R3). In other words, in the semiconductor device 110, a low oxygen concentration is set for only the regions that are desired to have a low contact resistance with the electrode. Therefore, there is little effect on the oxygen concentration in the third region R3 where the channel is formed.

Further, in the semiconductor device 110, the oxygen concentration in a region where the channel is formed (the third region R3) is greater than the oxygen concentration in the second region R2 that contacts the second electrode 12 and is greater than the oxygen concentration in the fourth region R4 that contacts the third electrode 13, and therefore, the on/off ratio of the current in the TFT is improved.

In this manner, in the semiconductor device 110, both a reduction in the contact resistance between the oxide semiconductor device 20 and the second electrode 12 and between the oxide semiconductor device 20 and the third electrode 13 and improvement of the on/off ratio of the current can be achieved.

Next, a first method for manufacturing the semiconductor device 110 will be described.

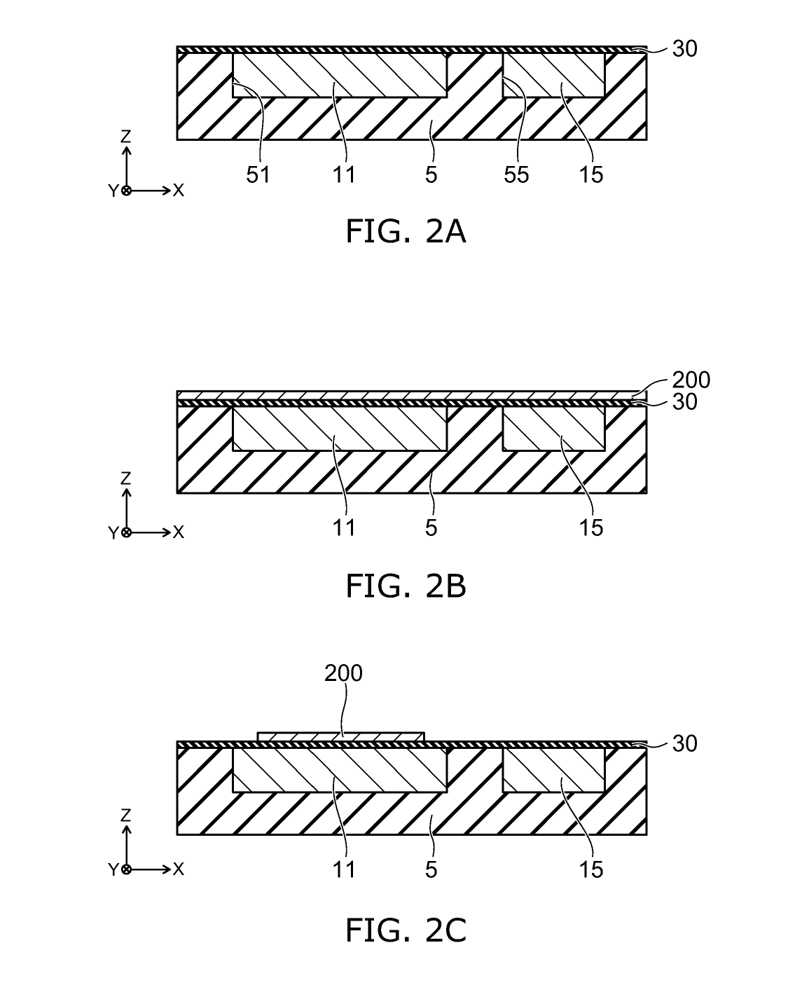

FIG. 2A to FIG. 4B are schematic cross-sectional views showing an example of the method for manufacturing a semiconductor device.

First, as shown in FIG. 2A, the first electrode 11 and the interconnection 15 that conducts with the first electrode 11 are formed in the insulating portion 5. The insulating portion 5 is provided, for example, on a substrate not illustrated. The first electrode 11 and the interconnection 15 are formed by, for example, a damascene method. In other words, etching is performed on a portion of the insulating portion 5 to form the grooves 51 and 55. Next, Cu, for example, is formed on the insulating portion 5 so as to fill in the grooves 51 and 55. Thereafter, the Cu is removed using CMP to leave only the Cu embedded in the grooves 51 and 55.

Next, the first insulating film 30 is formed on the insulating portion 5, the first electrode 11, and the interconnection 15. SiN, for example, is used as the first insulating film 30. The first insulating film 30 made of SiN is formed by using, for example, a low temperature CVD method. The thickness of the first insulating film 30 is, for example, about 30 nm.

Next, as shown in FIG. 2B, an oxide material film 200 is formed on the first insulating film 30. For example, In—Ga—Zn—O is used in the oxide material film 200. The oxide material film 200 is formed using, for example, a sputtering method. The thickness of the oxide material film 200 is, for example, not less than 5 nm and not more than 500 nm and is preferably not less than 30 nm and not more than 100 nm. An oxygen concentration of the oxide material film 200 formed here is, for example, not less than 1 wt % and not more that 15 wt %.

Next, as shown in FIG. 2C, patterning is performed on the oxide material film 200. A portion of the oxide material film 200 is removed by, for example, photolithography and etching. The oxide material film 200 on the interconnection 15 is removed by the etching. The oxide material film 200 on the first electrode 11 is left.

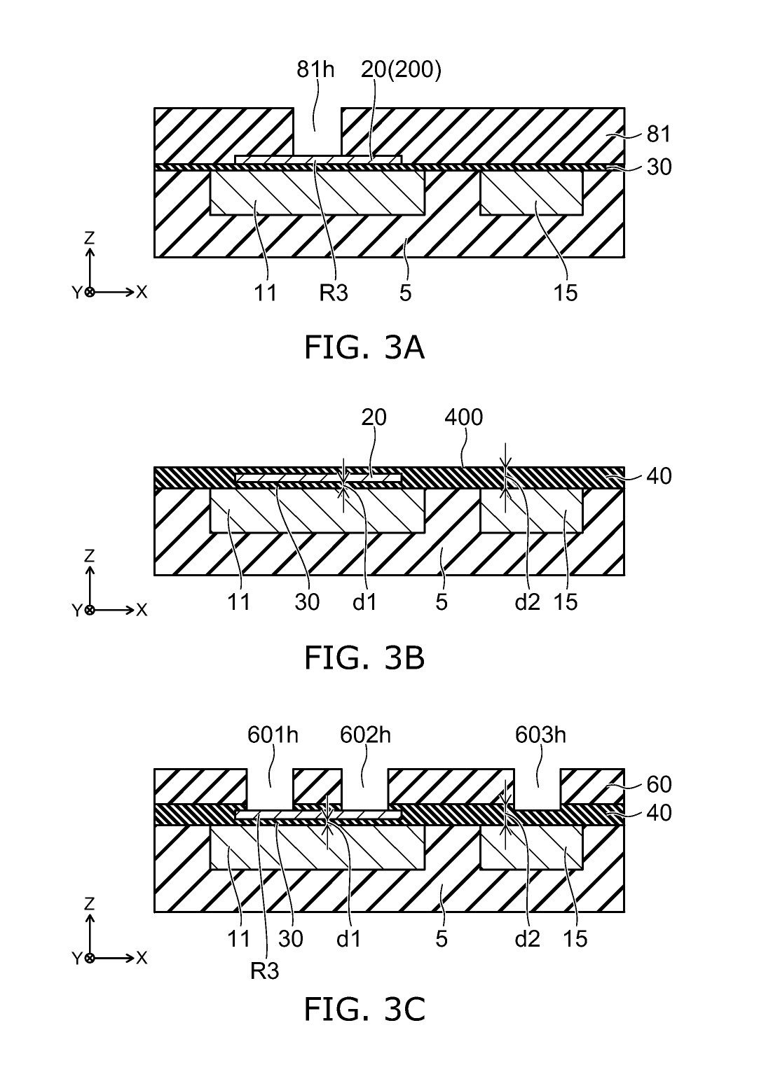

Next, as shown in FIG. 3A, a resist film 81 is formed on the first insulating film 30 and on the oxide material film 200. Further, an opening 81h is formed in a portion of the resist film 81 by photolithography. The opening 81h is provided in a center portion of the oxide material film 200 as viewed in the Z direction. A region of the oxide material film 200 that overlaps with the opening 81h as viewed in the Z direction is a region that becomes the third region R3.

Next, oxygen ions are implanted in the resist film 81 provided with the opening 81h for use as a mask. The oxygen ions are implanted into a portion of a region of the oxide material film 200 via the opening 81h. The oxygen concentration in the portion of the region of the oxide material film 200 where oxygen ions are implanted becomes greater than the oxygen concentration in other regions. The region where oxygen ions are implanted becomes the third region R3. The oxygen concentration in the third region R3 is, for example, not less than 15 wt % and not more than 25 wt %. Meanwhile, the oxygen concentration in the region where oxygen ions are not implanted maintains the same oxygen concentration as when the oxide material film 200 was formed. In other words, the oxide semiconductor film 20 is formed by the implantation of these oxygen ions. After the oxygen ions are implanted, the resist film 81 is removed.

Next, as shown in FIG. 3B, an insulating material film 400 is formed on the first insulating film 30 and on the oxide semiconductor film 20. SiN, for example, is used as the insulating material film 400. The insulating material film 400 made of SiN is formed by using, for example, a low temperature CVD method. The thickness of the insulating material film 400 is, for example, about 20 nm. This forms the second insulating film 40 on the interconnection 15. The thickness of the second insulating film 40 becomes the thickness d2 which is a sum of the thickness of the insulating material film 400 and the thickness d1 of the first insulating film 30.

Next, as shown in FIG. 3C, the protective film 60 is formed on the second insulating film 40. A plurality of contact holes (openings) 601h, 602h, and 603h is formed in the protective film 60 by photolithography and etching. Further, a plurality of interconnect grooves 62h, 63h, and 65h is formed by photolithography and etching.

The contact hole 601h is provided adjacent to the third region R3 as viewed in the Z direction. The contact hole 602h is provided adjacent to a side opposite to the contact hole 601h of the third region R3 as viewed in the Z direction.

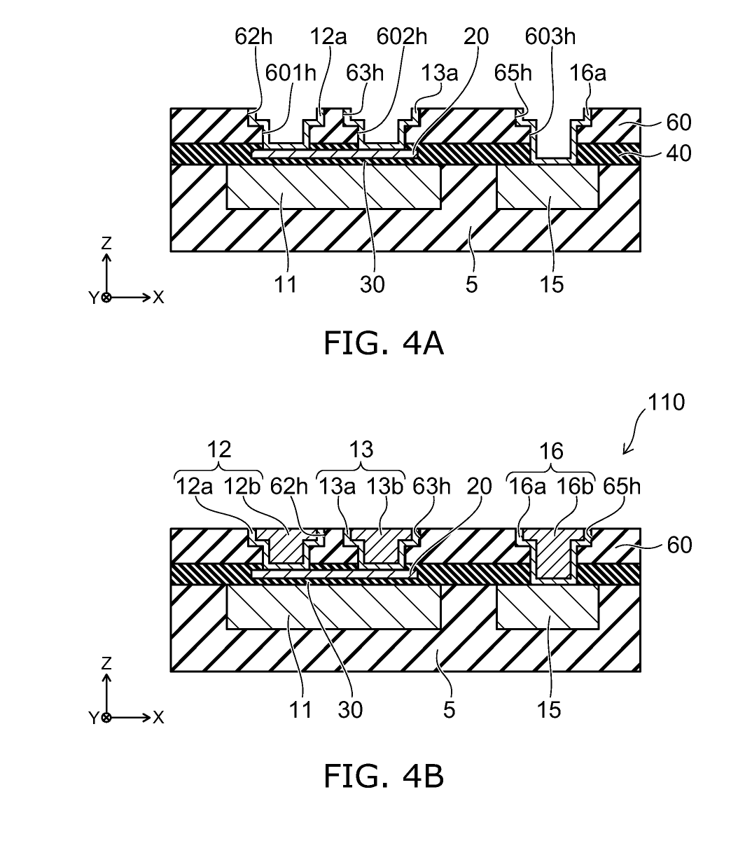

Next, as shown in FIG. 4A, the first barrier film 12a is formed on the interconnect groove 62h and on the inner wall and bottom of the contact hole 601h, the second barrier film 13a is formed on the interconnect groove 63h and on the inner wall and bottom of the contact hole 602h, and the third barrier film 16a is formed on the interconnect groove 65h and on the inner wall and bottom of the contact hole 603h. The first barrier film 12a and the second barrier film 13a contact the oxide semiconductor film 20, respectively. The third barrier film 16a contacts the interconnection 15. TaN, for example, is used in the first barrier film 12a, in the second barrier film 13a, and in the third barrier film 16a.

Next, as shown in FIG. 4B, the first conductive portion 12b is formed on the interconnect groove 62h and on the first barrier film 12a in the contact hole 601h, the second conductive portion 13b is formed on the interconnect groove 63h and on the second barrier film 13a in the contact hole 602h, and the third conductive portion 16b is formed on the interconnect groove 65h and on the third barrier film 16a in the contact hole 603h.

Cu, For example, is used in the first conductive portion 12b, in the second conductive portion 13b, and in the third conductive portion 16b. The first conductive portion 12b, the second conductive portion 13b, and the third conductive portion 16b are formed using, for example, a damascene method. In other words, Cu, for example, is formed on the protective film 60 so as to fill in the interconnect grooves 62h, 63h, and 65h as well as the contact holes 601h, 602h, and 603h. Thereafter, the Cu is removed using CMP to leave only the Cu embedded in the interconnect grooves 62h, 63h, and 65h and the contact holes 601h, 602h, and 603h.

Thereafter, a sintering process is performed using hydrogen if, for example, an Si-LSI is on the lower layer of the TFT. The semiconductor device 110 is completed according to the processes given above.

According to this method for manufacturing a semiconductor device, after the oxide semiconductor film 200 having a low oxygen concentration is formed, the third region R3 is formed having a higher oxygen concentration by implanting oxygen ions into a portion of the oxide material film 200. Thereby, the effect on the oxygen concentration in the second region R2 that contacts the second electrode 12 and on the oxygen concentration in the fourth region R4 that contacts the third electrode 13 is reduced, and the semiconductor device 110 having improved on/off ratio of the current is manufactured.

Next, a second method for manufacturing the semiconductor device 110 will be described.

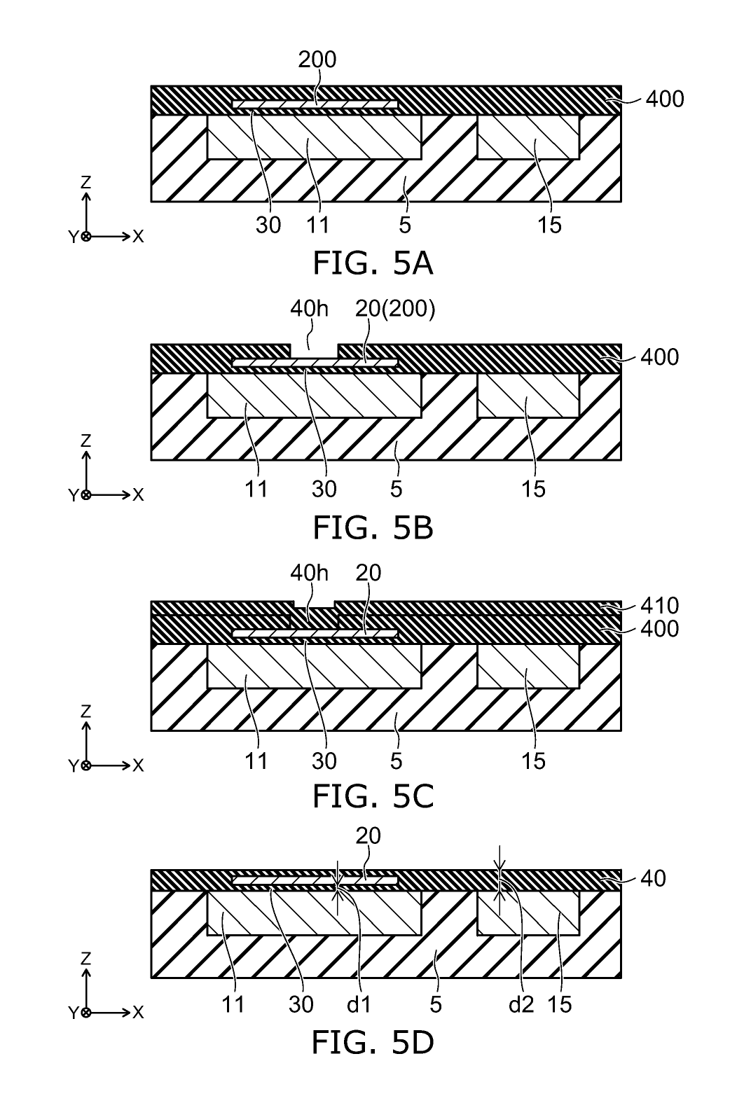

FIGS. 5A to 5D are schematic cross-sectional views illustrating an example of the method (II) for manufacturing a semiconductor device.

Note that in the second method for manufacturing a semiconductor device, the process shown in FIGS. 2A to 2C is similar to that of the first method for manufacturing a semiconductor device.

Next, as shown in FIG. 5A, an insulating material film 400 is formed on the first insulating film 30 and on the oxide semiconductor film 20. SiN, for example, is used as the insulating material film 400. The insulating material film 400 made of SiN is formed by using, for example, a low temperature CVD method. The thickness of the insulating material film 400 is, for example, about 20 nm.

Next, as shown in FIG. 5B, an opening 40h is formed on a portion of the insulating material film 400 and on the oxide material film 200. The opening 40h is provided in a center portion of the oxide material film 200 as viewed in the Z direction. A region of the oxide material film 200 that overlaps with the opening 40h as viewed in the Z direction is the region that becomes a third region R3.

Next, after the opening 40h is formed in the insulating material film 400, annealing (oxygen annealing) is performed in oxygen atmosphere. Annealing increases the oxygen concentration in a portion of the oxide material film 200 via the opening 40h. A region of a portion of the oxide material film 200 where the oxygen concentration was increased becomes the third region R3. The oxygen concentration in the third region R3 is, for example, not less than 15 wt % and not more than 25 wt %. Meanwhile, the oxygen concentration of the oxide material film 200 covered by the insulating material film 400 maintains the same oxygen concentration as when the oxide material film 200 was formed. The oxide semiconductor film 20 is formed by the oxygen annealing.

Next, as shown in FIG. 5C, a second insulating material film 410 is formed to plug the opening 40h. SiN, for example, is used as the second insulating material film 410. The second insulating material film 410 is formed so as to plug the opening 40h and is also form on the insulating material film 400.

Next, the second insulating material film 410 and the insulating material film 400 are flattened using a CMP method. This, as shown in FIG. 5D, forms the second insulating film 40 to have a predetermined thickness d2. Subsequent processes hereto are similar to the first method for manufacturing the semiconductor device 110 shown in FIG. 3C to FIG. 4B. The semiconductor device 110 is completed according to the process given above.

According to the second method for manufacturing the semiconductor device 110 in this manner, because oxygen is implanted by oxygen annealing and not by oxygen ion implantation, there is an advantage in that a high concentration of oxygen can be introduced in a short time period compared to the first method for manufacturing a semiconductor device described above.

### Second Embodiment

Next, a second embodiment will be described.

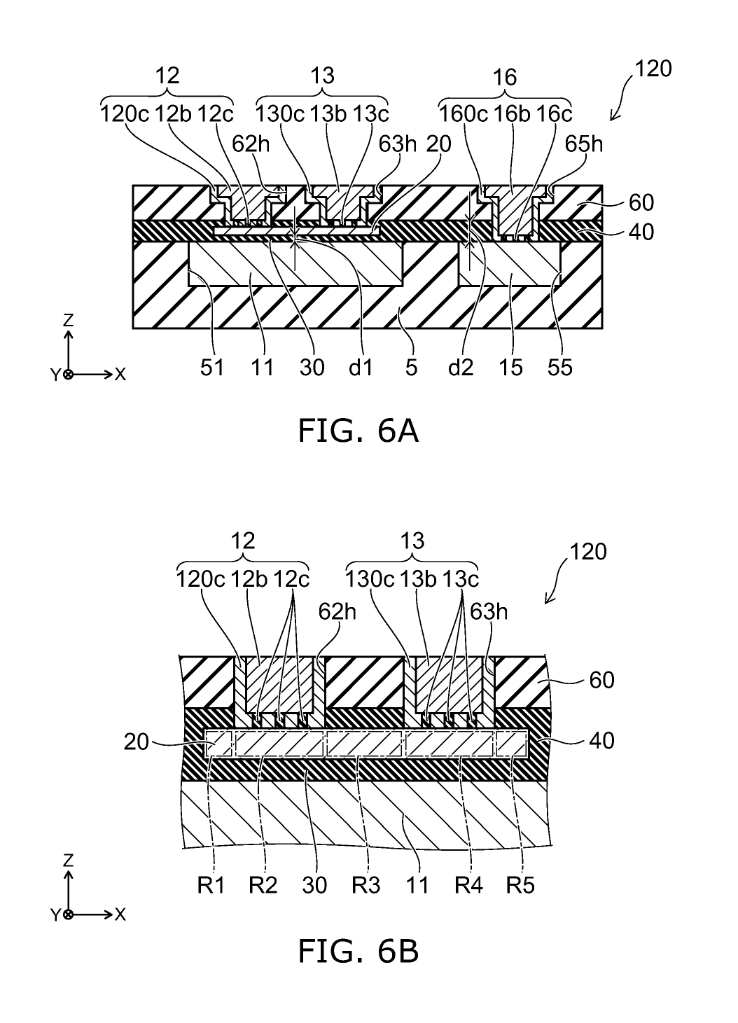

FIGS. 6A and 6B are schematic cross-sectional views illustrating a semiconductor device according to the second embodiment.

FIG. 6A shows a schematic cross-sectional view of a semiconductor device 120 according to the second embodiment. FIG. 6B shows a partially enlarged schematic cross-sectional view of the semiconductor device 120 according to the second embodiment.

As shown in FIG. 6A, the semiconductor device 120 according to the second embodiment includes a first electrode 11, an oxide semiconductor film 20, a first insulating film 30, a second electrode 12, and a third electrode 13, similar to that in the semiconductor device 110 according to the first embodiment. The semiconductor device 120 is, for example, a TFT.

In the semiconductor device 120, as shown in FIG. 6B, the second electrode 12 includes a first metal oxide portion 12c that is in contact with the second region R2 and has conductivity. In the semiconductor device 120, the third electrode 13 includes a second metal oxide portion 13c that is in contact with the fourth region R4 and has conductivity. In the semiconductor device 120, an interconnection 16 includes a third metal oxide portion 16c that is in contact with the interconnection 15 and has conductivity.

The first metal oxide portion 12c is a metal where the oxygen included in a portion (region making up the second region R2) of the oxide material film reacts with a first metal film 120c and has oxidized when forming the oxide semiconductor film 20. The first metal oxide portion 12c is a portion where at least a portion of the first metal film 120c has oxidized.

The first metal oxide portion 12c is provided partially or entirely of the portion where the second electrode 12 contacts the second region R2. Ruthenium (Ru) or titanium (Ti), for instance, that have conductivity even after oxidizing, may be used as the first metal film 120c. Thereby, the contact resistance between the second electrode 12 and the second region R2 is sufficiently reduced even when the first metal oxide portion 12c is provided between the first conductive portion 12b and the second region R2.

The second metal oxide portion 13c is a metal where the oxygen included in a portion (region making up the fourth region R4) of the oxide material film reacts with a second metal film 130c and has oxidized when forming the oxide semiconductor film 20. The second metal oxide portion 13c is a portion where at least a portion of the second metal film 130c has oxidized.

The second metal oxide portion 13c is provided partially or entirely of the portion where the third electrode 13 contacts the fourth region R4. Ru or Ti, for instance, that have conductivity even after oxidizing, may be used as the second metal film 130c. Thereby, the contact resistance between the third electrode 13 and the fourth region R4 is sufficiently reduced even when the second metal oxide portion 13c is provided between the second conductive portion 13b and the fourth region R4.

In the semiconductor device 120, the oxygen concentration in the second region R2 that contacts the second electrode 12 is set so as to be lowered by the first metal oxide portion 12c. In the semiconductor device 120, the oxygen concentration in the fourth region R4 that contacts the third electrode 13 is set so as to be lowered by the second metal oxide portion 13c. As such, there is little effect on the oxygen concentration in the surrounding regions of the second region R2 (the first region R1 and the third region R3) and on the oxygen concentration in the surrounding regions of the fourth region R4 (the fifth region R5 and the third region R3). In other words, in the semiconductor device 120, a low oxygen concentration is set for only the regions of the oxide semiconductor film 20 that are desired to have a low contact resistance with the electrode. Therefore, there is little effect on the oxygen concentration in the third region R3 where the channel is formed.

Further, in the semiconductor device 120, similar to the semiconductor device 110, the oxygen concentration in the region where the channel is formed (the third region R3) is greater than the oxygen concentration in the second region R2 that contacts the second electrode 12 and is greater than the oxygen concentration in the fourth region R4 that contacts the third electrode 13, and therefore, the on/off ratio of the current in the TFT is improved.

In this manner, in the semiconductor device 120, both a reduction in the contact resistance between the oxide semiconductor film 20 and the second electrode 12 and between the oxide semiconductor film 20 and the third electrode 13 and improvement of the on/off ratio of the current can be achieved.

Next, a method for manufacturing the semiconductor device 120 will be described.

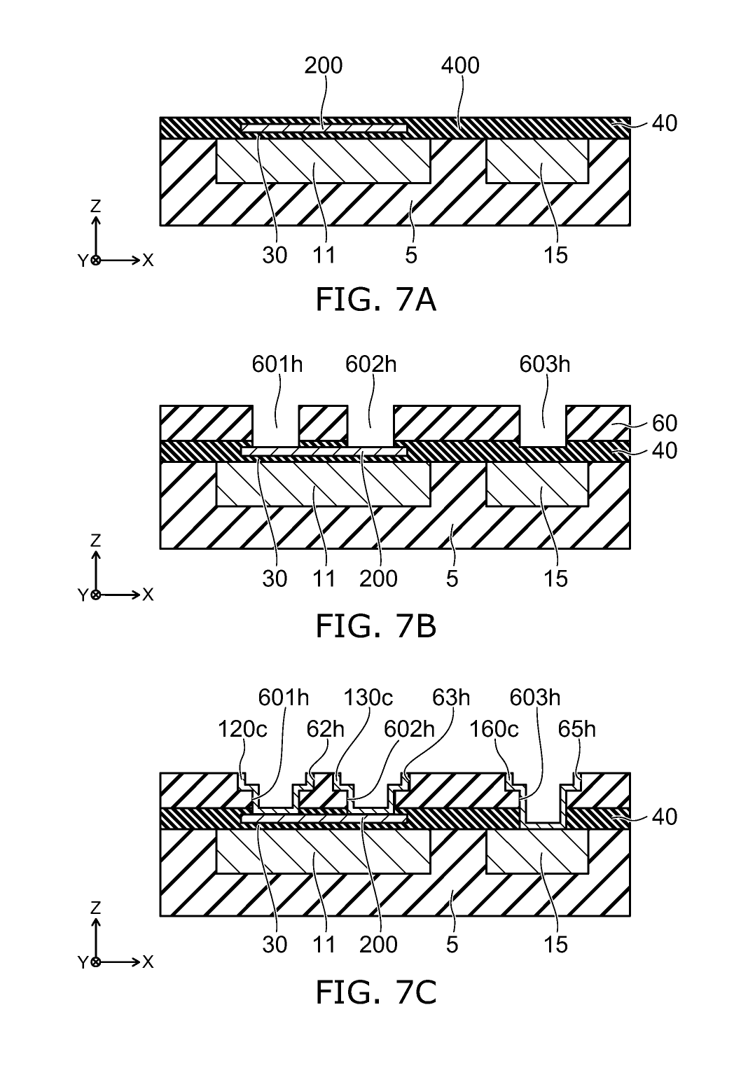

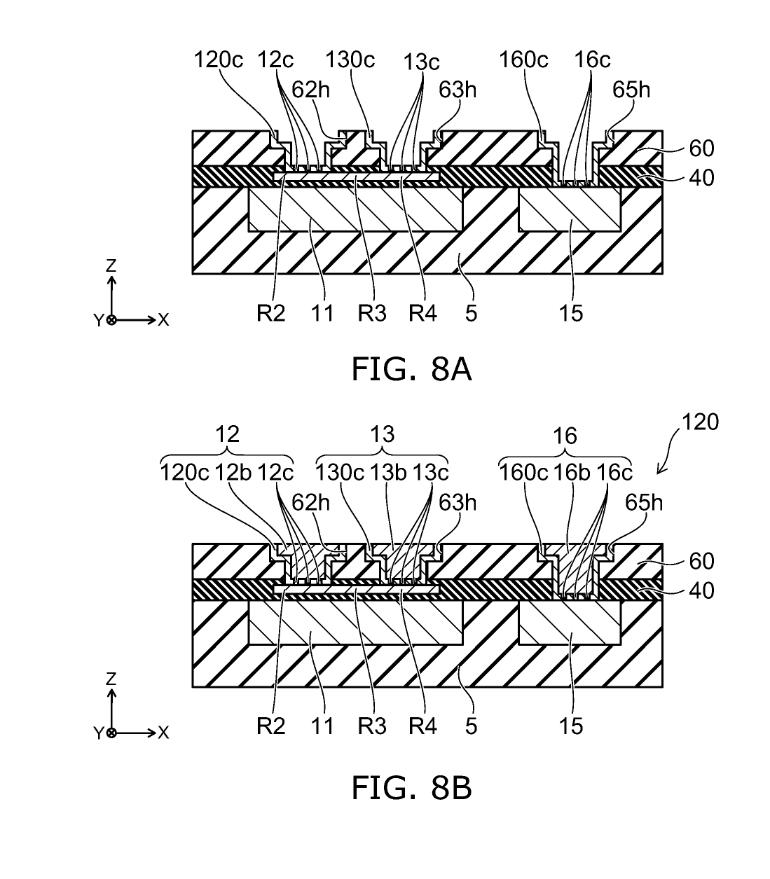

FIG. 7A to FIG. 8B are schematic cross-sectional views showing an example of the method for manufacturing a semiconductor device.

Note that in the method for manufacturing the semiconductor device 120, the process shown in FIGS. 2A to 2C is similar to that of the first method for manufacturing the semiconductor device 110. However, in the method for manufacturing the semiconductor device 120, the oxygen concentration of the oxide material film 200 is, for example, not less than 15 wt % and not more than 25 wt %.

Next, as shown in FIG. 7A, the insulating material film 400 is formed on the first insulating film 30 and on the oxide material film 200. SiN, for example, is used as the insulating material film 400. The insulating material film 400 made of SiN is formed by using, for example, a low temperature CVD method. The thickness of the insulating material film 400 is, for example, about 20 nm. This forms the second insulating film 40 on the interconnection 15. The thickness of the second insulating film 40 becomes the thickness d2 which is a sum of the thickness of the insulating material film 400 and the thickness d1 of the first insulating film 30.

Next, as shown in FIG. 7B, the protective film 60 is formed on the second insulating film 40. A plurality of contact holes 601h, 602h, and 603h are formed in the protective film 60 by photolithography and etching. Further, a plurality of interconnect grooves 62h, 63h, and 65h are formed by photolithography and etching.

The contact hole 601h is provided adjacent to the third region R3 as viewed in the Z direction. The contact hole 602h is provided adjacent to a side opposite the contact hole 601h of the third region R3 as viewed in the Z direction. Next, as shown in FIG. 7C, the first metal film 120c is formed on the interconnect groove 62h and on the inner wall and bottom of the contact hole 601h and the second metal film 130c is formed on the interconnect groove 63h and on the inner wall and bottom of the contact hole 602h. Further, the third metal film 160c is formed on the inner wall and bottom of the contact hole 603h.

The first metal film 120c, the second metal film 130c, and the third metal film 160c include a metal having reducing properties, respectively. A metal having conductivity even after oxidizing (for example, Ru or Ti) is included in the material of the first metal film 120c, the material of the second metal film 130c, and the material of the third metal film 160c.

Next, as shown in FIG. 8A, annealing is performed on the first metal film 120c, the second metal film 130c, and the third metal film 160c. At least a portion of the first metal film 120c becomes the first metal oxide portion 12c by this annealing. Forming the first metal oxide portion 12c reduces the region of a portion of the oxide material film 200 that contacts the first metal film 120c and thereby lowers the oxygen concentration. This forms the second region R2. The oxygen concentration in the second region R2 is, for example, not less than 1 wt % and not more than 15 wt %.

At least a portion of the second metal film 130c becomes the second metal oxide portion 13c by this annealing. Forming the second metal oxide portion 13c reduces the region of a portion of the oxide material film 200 that contacts the second metal film 130c and thereby lowers the oxygen concentration. This forms the fourth region R4. The oxygen concentration in the fourth region R4 is, for example, not less than 1 wt % and not more than 15 wt %.

Meanwhile, the oxygen concentration in regions that do not contact either the first metal film 120c or the second metal film 130c of the oxide material film 200 maintains the same oxygen concentration as when the oxide material film 200 was formed. The oxide semiconductor film 20 is formed by this annealing. Note that this annealing may also be performed after depositing the conductive portion described below.

Next, as shown in FIG. 8B, the first conductive portion 12b is formed on the interconnect groove 62h, on the first metal film 120c in the contact hole 601h, and on the first metal oxide portion 12c, the second conductive portion 13b is formed on the interconnect groove 63h, on the second metal film 130c in the contact hole 602h, and on the second metal oxide portion 13c, and the third conductive portion 16b is formed on the interconnect groove 65h, on the third metal film 160c in the contact hole 603h, and on the third metal oxide portion 16c.

Cu, For example, is used in the first conductive portion 12b, in the second conductive portion 13b, and in the third conductive portion 16b. The first conductive portion 12b, the second conductive portion 13b, and the third conductive portion 16b are formed using, for example, a damascene method. In other words, Cu, for example, is formed on the protective film 60 so as to fill in the interconnect grooves 62h, 63h, and 65h as well as the contact holes 601h, 602h, and 603h. Thereafter, the Cu is removed using CMP to leave only the Cu embedded in the contact holes 62h, 63h, and 65h.

Thereafter, a sintering process is performed using hydrogen if, for example, an Si-LSI is on the lower layer of the TFT. The semiconductor device 120 is completed according to the process given above.

According to this method for manufacturing a semiconductor device, after the oxide semiconductor film 20 having a high oxygen concentration is formed, the second region R2 and the fourth region R4 is formed having lower oxygen concentrations by forming metal films having reducing properties in a portion of the oxide material film 200. Thereby, the effect on the oxygen concentration in the third region R3 is suppressed, and the semiconductor device 120 having a reduced contact resistance between the oxide semiconductor film 20 and the second electrode 12 and between the oxide semiconductor film 20 and the third electrode 13 is manufactured.

### Third Embodiment

Next, a third embodiment will be described.

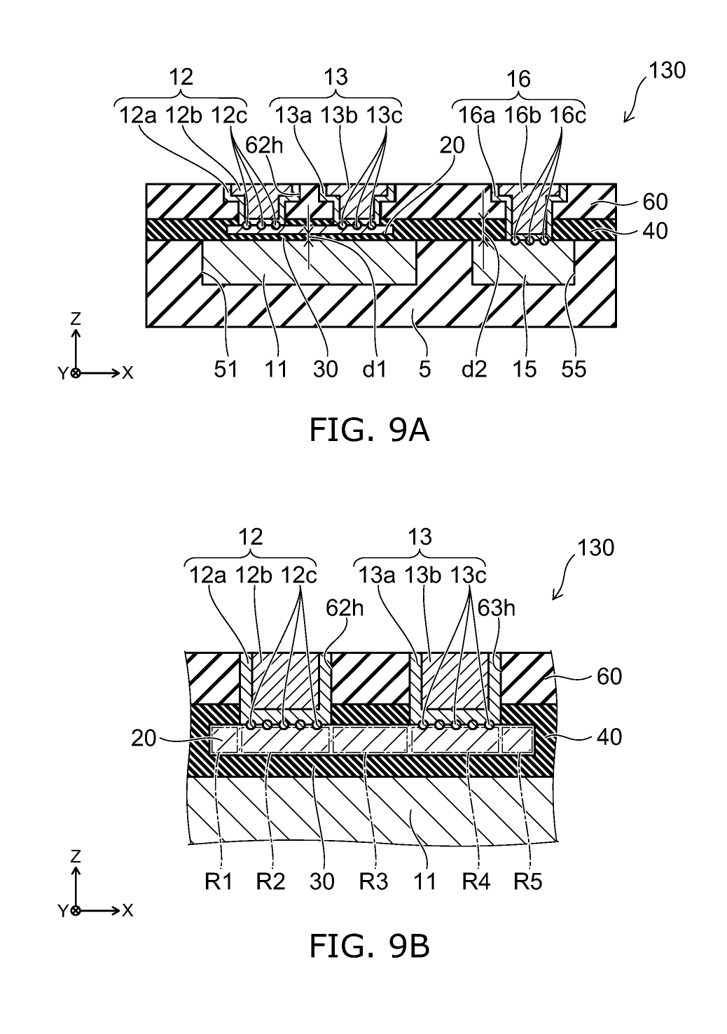

FIGS. 9A and 9B are schematic cross-sectional views illustrating a semiconductor device according to the third embodiment.

FIG. 9A shows a schematic cross-sectional view of a semiconductor device 130 according to the third embodiment. FIG. 9B shows a partially enlarged schematic cross-sectional view of the semiconductor device 130 according to the third embodiment.

As shown in FIG. 9A, the semiconductor device 130 according to the third embodiment includes a first electrode 11, an oxide semiconductor film 20, a first insulating film 30, a second electrode 12, and a third electrode 13, similar to the semiconductor device 110 according to the first embodiment. The semiconductor device 130 is, for example, a TFT.

In the semiconductor device 130, as shown in FIG. 9B, the second electrode 12 includes a first metal oxide portion 12c that is in contact with the second region R2 and has conductivity. The first metal oxide portion 12c includes a plurality of granular metal oxides. The first metal oxide portion 12c is provided between the first barrier film 12a and the second region R2.

The first metal oxide portion 12c includes a granular metal oxide where the oxygen included in a portion (region making up the second region R2) of the oxide material film reacts with the granular metal and has oxidized when forming the oxide semiconductor film 20. The granular metal oxide is interspersed in a portion where the second electrode 12 contacts the second region R2. Therefore, a portion of the first barrier film 12a contacts the second region R2. Accordingly, the contact resistance between the second electrode 12 and the second region R2 can be sufficiently reduced even when the first metal oxide portion 12c is provided between the first conductive portion 12b and the second region R2.

In the semiconductor device 130, the third electrode 13 includes a second metal oxide portion 13c that is in contact with the fourth region R4 and has conductivity. The second metal oxide portion 13c is provided between the second barrier film 13a and the fourth region R4.

The second metal oxide portion 13c includes a granular metal oxide where the oxygen included in the portion (region making up the fourth region R4) of the oxide material film reacts with the granular metal and has oxidized when forming the oxide semiconductor film 20. The granular metal oxide is interspersed in a portion where the third electrode 13 contacts the fourth region R4. Therefore, a portion of the second barrier film 13a contacts the fourth region R4. Accordingly, the contact resistance between the third electrode 13 and the fourth region R4 can be sufficiently reduced even when the second metal oxide portion 13c is provided between the second conductive portion 13b and the fourth region R4.

The third metal oxide portion 16c includes a plurality of granular metal oxides.

At least one of, for example, Ta, Al, and Ti is used as the granular metal. The diameter of the granular metal is approximately, for example, not less than 1 nm and not more than 5 nm.

In the semiconductor device 130, the oxygen concentration in the second region R2 that contacts the second electrode 12 is set so as to be lowered by the first metal oxide portion 12c. In the semiconductor device 130, the oxygen concentration in the fourth region R4 that contacts the third electrode 13 is set so as to be lowered by the second metal oxide portion 13c. As such, there is little effect on the oxygen concentration in the surrounding regions of the second region R2 (the first region R1 and the third region R3) and on the oxygen concentration in the surrounding regions of the fourth region R4 (the fifth region R5 and the third region R3). In other words, in the semiconductor device 130, a low oxygen concentration is set for only the regions of the oxide semiconductor film 20 that are desired to have a low contact resistance with the electrode. Therefore, there is little effect on the oxygen concentration in the third region R3 where the channel is formed.

Further, in the semiconductor device 130, similar to the semiconductor devices 110 and 120, the oxygen concentration in the region where the channel is formed (the third region R3) is greater than the oxygen concentration in the second region R2 that contacts the second electrode 12 and is greater than the oxygen concentration in the fourth region R4 that contacts the third electrode 13, and therefore, the on/off ratio of the current in the TFT is improved.

Next, a method for manufacturing the semiconductor device 130 will be described.

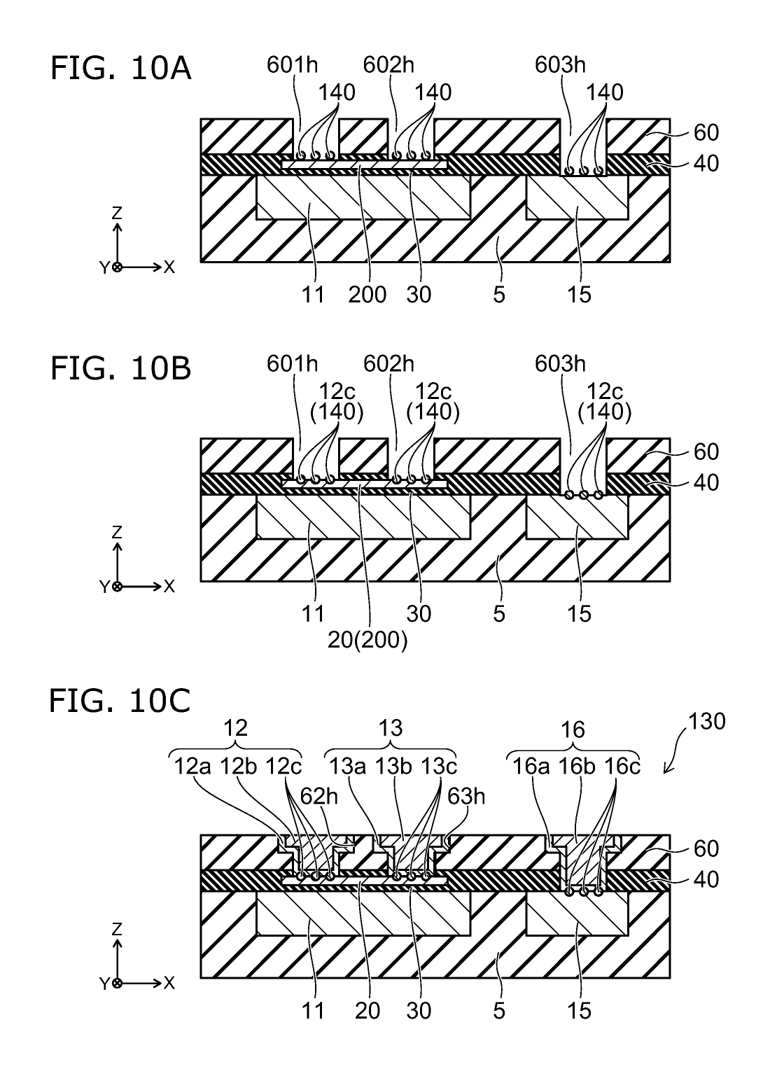

FIGS. 10A to 10C are schematic cross-sectional views showing an example of the method for manufacturing a semiconductor device.

Note that, in the method for manufacturing the semiconductor device 130, the process shown in FIGS. 2A to 2C is similar to that of the method (I) for manufacturing the semiconductor device 110 and the process shown in FIGS. 7A and 7B is similar to that of the method for manufacturing the semiconductor device 120. However, in the method for manufacturing the semiconductor device 130, the oxygen concentration of the oxide material film 200 is, for example, not less than 15 wt % and not more than 25 wt %.

Next, as shown in FIG. 10A, the granular metal 140 is formed on the bottom of the contact holes 601h, 602h, and 603h. The granular metal 140 is not formed on the entire surface of the bottom of the contact holes 601h, 602h, and 603h. At least one of an easily reducing Ta, Al, and Ti is used in the granular metal 140.

Next, as shown in FIG. 10B, a reduction treatment for oxygen is performed by the granular metal 140 formed on the bottom of the contact holes 601h, 602h, and 603h. The reduction treatment may be performed, for example, by applying annealing. Thereby, the granular metal 140 formed on the bottom of the contact hole 601h becomes the granular metal oxide (first metal oxide portion 12c). Forming the first metal oxide portion 12c lowers the oxygen concentration in a region of a portion of the oxide material film 200 that contacts the first metal film 120c. This forms the second region R2. The oxygen concentration in the second region R2 is, for example, not less than 1 wt % and not more than 15 wt %.

Furthermore, the reduction treatment also makes the granular metal 140 formed on the bottom of the contact hole 602h to be the granular metal oxide (second metal oxide portion 13c). Forming the second metal oxide portion 13c lowers the oxygen concentration in the region of a portion of the oxide material film 200 that contacts the second metal film 130c. This forms the fourth region R4. The oxygen concentration in the fourth region R4 is, for example, not less than 1 wt % and not more than 15 wt %.

Meanwhile, the oxygen concentration in regions that do not contact the granular metal 140 of the oxide material film 200 maintains the same oxygen concentration as when the oxide material film 200 was formed. The oxide semiconductor film 20 is formed by this reduction treatment. Moreover, this reduction treatment may also be performed after depositing the conductive portion described below.

Next, as shown in FIG. 10C, the first barrier film 12a is formed on the interconnect groove 62h and on the inner wall and bottom of the contact hole 601h, and the second barrier film 13a is formed on the interconnect groove 63h and on the inner wall and bottom of the contact hole 602h. Further, the third barrier film 16a is formed on the interconnect groove 65h and on the inner wall and bottom of the contact hole 603h.

Next, the first conductive portion 12b is formed on the first barrier film 12a in the contact hole 62h and on the first metal oxide portion 12c, the second conductive portion 13b is formed on the second barrier film 13a in the contact hole 63h and on the second metal oxide portion 13c, and the third conductive portion 16b is formed on the third barrier film 16a in the contact hole 65h.

Cu, For example, is used in the first conductive portion 12b, in the second conductive portion 13b, and in the third conductive portion 16b. The first conductive portion 12b, the second conductive portion 13b, and the third conductive portion 16b are formed using, for example, a damascene method. In other words, Cu, for example, is formed on the protective film 60 so as to fill in the contact holes 62h, 63h, and 65h. Thereafter, the Cu is removed using CMP to leave only the Cu embedded in the contact holes 62h, 63h, and 65h.

Thereafter, a sintering process is performed using hydrogen if, for example, an Si-LSI is on the lower layer of the TFT. The semiconductor device 130 is completed according to the process given above.

According to this method for manufacturing a semiconductor device, after the oxide semiconductor film 20 having a high oxygen concentration is formed, the second region R2 and the fourth region R4 is formed having lower oxygen concentrations by forming granular metal having reducing properties in a portion of the oxide material film 200. In doing so, the extent of formation of the second region R2 and the fourth region R4 is limited by the amount and placement of the granular metal. Thereby, the effect on the oxygen concentration in the third region R3 is suppressed, and the semiconductor device 120 having a reduced contact resistance between the oxide semiconductor film 20 and the second electrode 12 and the third electrode 13 is manufactured.

In the semiconductor devices 110, 120, and 130 described above, the oxygen concentration in the second region R2 and the oxygen concentration in the fourth region R4 may be uniform in the Z direction or may be given a distribution. If given the distribution, it is only necessary that the oxygen concentration on the second electrode 12 side is the lowest in the second region R2, and the oxygen concentration on the third electrode 13 side is the lowest in the fourth region R4.

### Fourth Embodiment

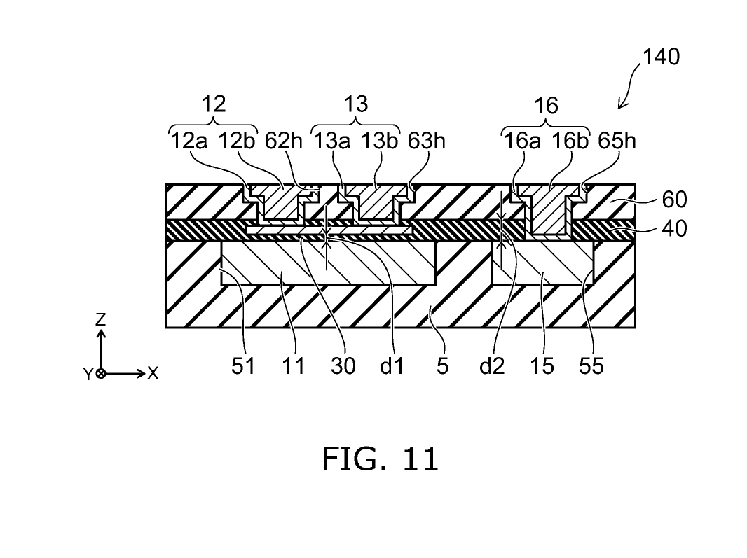

FIG. 11 is a schematic cross-sectional view illustrating a semiconductor device according to the fourth embodiment.

The semiconductor device 140 according to the fourth embodiment, as illustrated in FIG. 11, includes a first electrode 11, an oxide semiconductor film 20, a first insulating film 30, a second electrode 12 and a third electrode 13. The semiconductor device 140 is, for example, a TFT. The first electrode 11 is, for example, a gate electrode for the TFT. The second electrode 12 is, for example, a source electrode for the TFT. The third electrode 13 is, for example, a drain electrode for the TFT. The oxide semiconductor film 20 is, for example, an active layer where a channel for the TFT is formed. The first insulating film 30 is, for example, a portion of the gate insulating film for the TFT.

In the semiconductor device 140, the oxide semiconductor film 20 is provided between the first electrode 11 and the second electrode 12 and the third electrode 13. Note that the first electrode 11, the second electrode 12, and the third electrode 13 may be provided together with on the oxide semiconductor film 20.

The first electrode 11 is embedded in a groove 51 provided in an insulating portion 5. Cu may be used, for example, in the first electrode 11. The first electrode 11 is formed by, for example, a damascene method. In the embodiment, the first electrode 11 is embedded in the groove 51 of the insulating portion 5 by a damascene method using Cu. The first electrode 11 is provided in, for example, an island shape. The first electrode 11 may be provided in a line shape.

The oxide semiconductor film 20 is provided on the first electrode 11. For example, indium (In)-gallium (Ga)-zinc (Zn)-oxygen (O) are provided in the oxide semiconductor film 20. An oxide including In or Zn other than In—Ga—Zn—O, such as In—O film, Zn—O film, In—Zn—O film, In—Ga—O film, Al—Zn—O film, and In—Al—Zn—O film may be used in the oxide semiconductor film 20. A thickness of the oxide semiconductor film 20 is, for example, not less than 5 nanometers (nm) and not more than 100 nm.

The first insulating film 30 is provided between the first electrode 11 and the oxide semiconductor film 20. The first insulating film 30 is stacked, for example, on the first electrode 11. SiN, for example, is used as the first insulating film 30. Other than SiN, SiO₂, SiON, or even HfO₂ or HfSiON or the like may be used as the first insulating film 30. The use of Cu as the first electrode 11 and SiN as the first insulating film 30 effectively suppresses the diffusion of Cu into the oxide semiconductor film 20. The thickness of the first insulating film 30 is, for example, not less than 5 nm and not more than 500 nm.

The oxide semiconductor film 20 is covered by the second insulating film 40. The second insulating film 40 is provided so as to cover a face other than a face that contacts the first insulating film 30 of the oxide semiconductor film 20. The second insulating film 40 is also provided on the interconnection 15 arranged with the first electrode 11. The second insulating film 40 suppresses a foreign material from being introduced from an outer side of the oxide semiconductor film 20 to an inner side thereof. A foreign material includes substances including, for example, hydrogen.

The second insulating film 40 includes, for example, SiN. The second insulating film 40 may include one selected from the group consisting of Al₂O₃), TiO₂), or Ta₂O₅). The material for the second insulating film 40 may be the same or different material as that of the first insulating film 30.

A protective film 60 is provided on the second insulating film 40. For the protective film 60, SiO₂ is, for example, used. The protective film 60 can be formed by using, for example, CVD. A thickness of the protective film 60 is, for example, not less than 100 nm and not more than 1000 nm. The second insulating film 40 and the protective film 60 function as interlayer insulating films provided on the first electrode 11 and the interconnection 15.

The second electrode 12 contacts a portion of the oxide semiconductor film 20. The second electrode 12 is provided in a contact hole 62h provided in the protective film 60 and the second insulating film 40. The contact hole 62h is provided from the surface of the protective film 60 to the oxide semiconductor film 20.

The second electrode 12 includes, for example, a first barrier film 12a and a first conductive portion 12b. The first barrier film 12a is formed along the inner wall of the contact hole 62h and on the bottom of the contact hole 62h. The first barrier film 12a contacts a portion of the oxide semiconductor film 20 on the bottom of the contact hole 62h. The first conductive portion 12b is embedded in the contact hole 62h with the first barrier film 12a therebetween.

TaN, for example, is used in the first barrier film 12a. Cu, for example, is used in the first conductive portion 12b. The first conductive portion 12b is formed in the contact hole 62h using, for example, a damascene method. The first barrier film 12a functions as a barrier film that suppresses the material of the first conductive portion 12b (for example, Cu), or substances included in the first conductive portion 12b (for example, substances including hydrogen), from being introduced to the oxide semiconductor film 20. Note that Al or the like may be used instead of Cu for the second electrode 12.

The third electrode 13 contacts another portion of the oxide semiconductor film 20. The third electrode 13 is provided in a contact hole 63h provided in the protective film 60 and the second insulating film 40. The contact hole 63h is provided from the surface of the protective film 60 to the oxide semiconductor film 20.

The third electrode 13 includes, for example, a second barrier film 13a and a second conductive portion 13b. The second barrier film 13a is formed along the inner wall of the contact hole 63h and on the bottom of the contact hole 63h. The second barrier film 13a contacts another portion of the oxide semiconductor film 20 on the bottom of the contact hole 63h. The second conductive portion 13b is embedded in the contact hole 63h with the second barrier film 13a therebetween.

TaN, for example, is used in the second barrier film 13a. Cu, for example, is used in the second conductive portion 13b. The second conductive portion 13b is formed in the contact hole 63h using, for example, a damascene method. The second barrier film 13a functions as a barrier film that suppresses the material of the second conductive portion 13b (for example, Cu), or substances included in the second conductive portion 13b (for example, substances including hydrogen), from being introduced to the oxide semiconductor film 20. Note that Al or the like may be used instead of Cu for the third electrode 13.

The interconnection 15 is embedded in the groove 55 provided on the insulating portion 55. Cu is used, for example, in the interconnection 15. The interconnection 15 is formed by, for example, a damascene method. In the embodiment, the interconnection 15 is embedded in the groove 55 of the insulating portion 5 by a damascene method using Cu. The interconnection 15 conducts with, for example, the first electrode 11.

The second insulating film 40 and the protective film 60 are provided on the interconnection 15. The contact hole 65h is provided in the first protective film and the protective film 60 on the interconnection 15. The contact hole 65h is provided from the surface of the protective film 60 to the interconnection 15.

An interconnection 16 is provided in the contact hole 65h. The interconnection 16 is a contact interconnection with the interconnection 15. The interconnection 16 includes, for example, a third barrier film 16a and a third conductive portion 16b. The third barrier film 16a is formed along the inner wall of the contact hole 65h and on the bottom of the contact hole 65h. The third barrier film 16a contacts the interconnection 15 on the bottom of the contact hole 65h. The third conductive portion 16b is embedded in the contact hole 65h with the third barrier film 16a therebetween.

TaN, for example, is used in the third barrier film 16a. Cu, for example, is used in the third conductive portion 16b. The third conductive portion 16b is formed in the contact hole 65h using, for example, a damascene method. Note that Al or the like may be used instead of Cu for the interconnection 16.

The thickness d2 of the second insulating film 40 provided on the interconnection 15 is thicker than the thickness d1 of the first insulating film 30. The thickness d1 of the first insulating film 30 is, for example, about 30 nm. The thickness d2 of the second insulating film 40 is, for example, about 50 nm. The thickness d1 of the first insulating film 30 is desired to be thin in order to increase the drive capability and transconductance of the semiconductor device 140. Meanwhile, a certain degree of thickness is required in the thickness d2 of the second insulating film 40 for forming the interconnection 16 using a damascene method. In other words, formation of the groove becomes difficult when forming the interconnection 16 using a damascene method when the thickness d2 of the second insulating film 40 is as thin as the thickness d1 of the first insulating film 30. Therefore, in the semiconductor device 140, the thickness d2 of the second insulating film 40 is thicker than the thickness d1 of the first insulating film 30. Thereby, a secure contact can be achieved between the interconnection 16 and the interconnection 15 when forming the interconnection 16 using a damascene method.

Next, a method for manufacturing the semiconductor device 140 will be described.

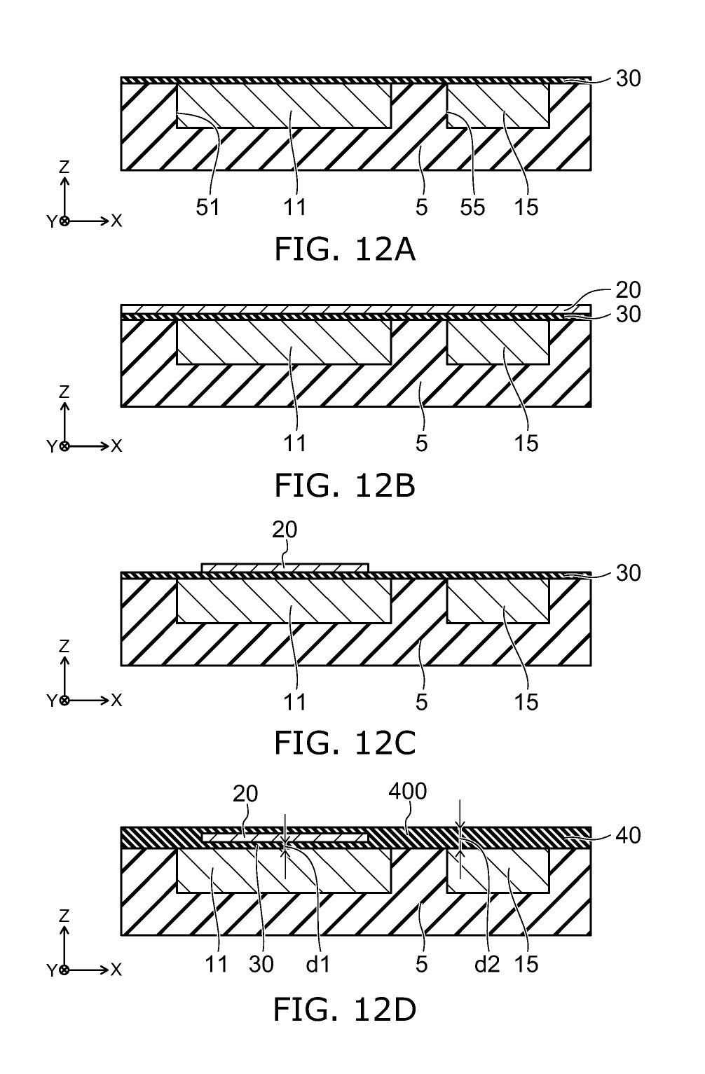

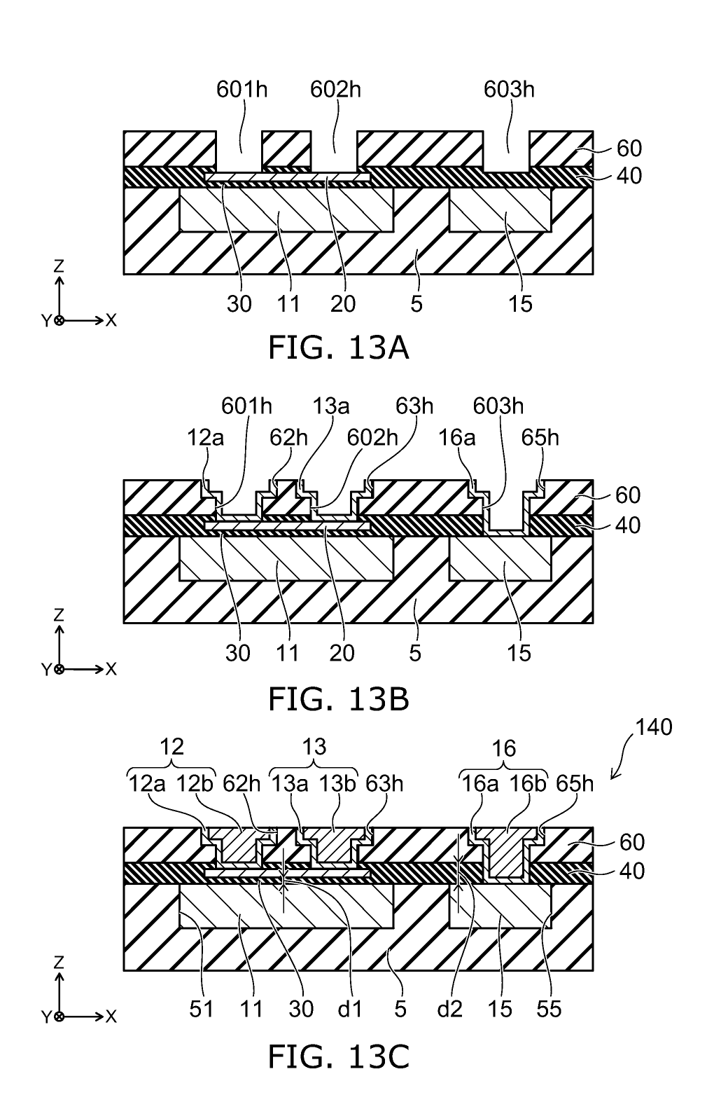

FIG. 12A to FIG. 13C are schematic cross-sectional views illustrating an example of the method for manufacturing a semiconductor device.

First, as shown in FIG. 12A, the first electrode 11 and interconnection 15 that conducts with the first electrode 11 are formed in the insulating portion 5. The insulating portion 5 is provided, for example, on a substrate not illustrated. The first electrode 11 and the interconnection 15 are formed by, for example, a damascene method. In other words, etching is performed on a portion of the insulating portion 5 to form the grooves 51 and 55. Next, Cu, for example, is formed on the insulating portion 5 so as to fill in the grooves 51 and 55. Thereafter, the Cu is removed using CMP to leave only the Cu embedded in the grooves 51 and 55.

Next, the first insulating film 30 is formed on the insulating portion 5, the first electrode 11, and the interconnection 15. SiN, for example, is used as the first insulating film 30. The first insulating film 30 made of SiN is be formed by using, for example, a low temperature CVD method. The thickness of the first insulating film 30 is, for example, about 30 nm.

Next, as shown in FIG. 12B, the oxide semiconductor film 20 is formed on the first insulating film 30. For example, In—Ga—Zn—O is used in the oxide semiconductor film 20. The oxide semiconductor film 20 is formed using, for example, a sputtering method. A thickness of the oxide semiconductor film 20 is, for example, not less than 5 nm and not more than 500 nm, and is preferably not less than 30 nm and not more than 100 nm.

Next, as shown in FIG. 12C, patterning is performed on the oxide semiconductor film 20. A portion of the oxide semiconductor film 20 is removed by, for example, photolithography and etching. The oxide semiconductor film 20 on the interconnection 15 is removed by the etching. The oxide semiconductor film 20 on the first electrode 11 is left.

Next, as shown in FIG. 12D, the insulating material film 400 is formed on the first insulating film 30 and on the oxide semiconductor film 20. SiN, for example, is used as the insulating material film 400. The insulating material film 400 made of SiN is formed by using, for example, a low temperature CVD method. The thickness of the insulating material film 400 is be, for example, about 20 nm. This forms the second insulating film 40 on the interconnection 15. The thickness of the second insulating film 40 becomes the thickness d2 which is a sum of the thickness of the insulating material film 400 and the thickness d1 of the first insulating film 30. The thickness d2 of the second insulating film 40 is thicker than the thickness d1 of the first insulating film 30. In the embodiment, the thickness d1 is, for example, 30 nm, and the thickness d2 is, for example, 50 nm.

Next, as shown in FIG. 13A, the protective film 60 is formed on the second insulating film 40. A plurality of contact holes 601h, 602h, and 603h is formed in the protective film 60 by photolithography and etching. Further, a plurality of interconnect grooves 62h, 63h, and 65h are formed by photolithography and etching.

Next, the first barrier film 12a is formed on the interconnect groove 62h and on the inner wall and bottom of the contact hole 601h, the second barrier film 13a is formed on the interconnect groove 63h and on the inner wall and bottom of the contact hole 602h, and the third barrier film 16a is formed on the interconnect groove 65h and on the inner wall and bottom of the contact hole 603h. The first barrier film 12a and the second barrier film 13a contact the oxide semiconductor film 20, respectively. The third barrier film 16a contacts the interconnection 15. TaN, for example, is used in the first barrier film 12a, in the second barrier film 13a, and in the third barrier film 16a.

Next, as shown in FIG. 13C, the first conductive portion 12b is formed on the interconnect groove 62h and on the first barrier film 12a in the contact hole 601h, the second conductive portion 13b is formed on the interconnect groove 63h and on the second barrier film 13a in the contact hole 602h, and the third conductive portion 16b is formed on the interconnect groove 65h and on the third barrier film 16a in the contact hole 603h.

Cu, For example, is used in the first conductive portion 12b, in the second conductive portion 13b, and in the third conductive portion 16b. The first conductive portion 12b, the second conductive portion 13b, and the third conductive portion 16b are formed using, for example, a damascene method. In other words, Cu, for example, is formed on the protective film 60 so as to fill in the interconnect grooves 62h, 63h, and 65h as well as the contact holes 601h, 602h, and 603h. Thereafter, the Cu is removed using CMP to leave only the Cu embedded in the interconnect grooves 62h, 63h, and 65h and the contact holes 601h, 602h, and 603h.

Thereafter, a sintering process is performed using hydrogen if, for example, an Si-LSI is on the lower layer of the TFT. The semiconductor device 140 is completed according to the processes given above.

According to this type of method for manufacturing a semiconductor device, thinning the thickness d1 of the first insulating film 30 allows drive capability and transconductance of the semiconductor device 140 to be improved. Further, thickening the thickness d2 of the second insulating film 40 allows the interconnection 16 to be formed with good precision using a damascene method.

As described above, according to the semiconductor device as in the embodiments and the method of manufacturing the same, characteristics can be improved.

The embodiments have been described above, but the invention is not limited to these examples. For example, in the embodiments described above, examples were given using a TFT as the semiconductor devices 110, 120, 130, and 140, but a transistor other than this may also be used. Also, in the above described embodiments, when constituents are appropriately added, removed or changed in design by a person skilled in the art, or the characteristics of the various embodiments are appropriately combined; provided that the resulting configuration does not depart from the spirit of the invention, it falls within in the scope of the invention.

What is claimed is:

1. A semiconductor device, comprising:
a first electrode;
an oxide semiconductor film having a first region, a second region, a third region, a fourth region, and a fifth region aligned in one direction;
an insulating film provided between the first electrode and the oxide semiconductor film;
a second electrode provided on the second region, the second electrode contacting the second region with an entire upper face of the second region as a contact face; and
a third electrode provided on the fourth region, the third electrode contacting the fourth region with an entire upper face of the fourth region as a contact face,
an oxygen concentration in the second region being less than an oxygen concentration in the third region, and
an oxygen concentration in the fourth region being less than the oxygen concentration in the third region.

2. The device according to claim 1, wherein the oxygen concentration in the second region is not less than 1 wt % and not more than 15 wt %,
the oxygen concentration in the third region is not less than 15 wt % and not more than 25 wt %, and
the oxygen concentration in the fourth region is not less than 1 wt % and not more than 15 wt %.

3. The device according to claim 2, wherein the oxygen concentration in the second region is less than each of an oxygen concentration in the first region and an oxygen concentration in the fifth region, and
the oxygen concentration in the fourth region is less than each of the oxygen concentration in the first region and the oxygen concentration in the fifth region.

4. The device according to claim 1, wherein the second electrode includes a first metal oxide portion being in contact with the second region and having conductivity, and
the third electrode includes a second metal oxide portion being in contact with the fourth region and having conductivity.

5. The device according to claim 4, wherein the first metal oxide portion includes granular metal oxides, and
the second metal oxide portion includes granular metal oxides.

6. The device according to claim 4, wherein the first metal oxide portion includes at least one of Ru and Ti, and
the second metal oxide portion includes at least one of Ru and Ti.

7. The device according to claim 1, wherein the oxide semiconductor film includes at least one of In—O and Zn—O.

8. The device according to claim 1, wherein the first electrode includes Cu.

9. The device according to claim 1, wherein the second electrode and the third electrode include Cu.

10. The device according to claim 1, wherein the insulating film includes SiN.

11. A semiconductor device, comprising:
a first electrode;
an interconnection provided together with the first electrode;
an oxide semiconductor film provided on the first electrode;
a first insulating film provided between the first electrode and the oxide semiconductor film, the first insulating film having a first thickness;
a second electrode electrically connected to the oxide semiconductor film;
a third electrode electrically connected to the oxide semiconductor film; and
a second insulating film provided on the interconnection, the second insulating film having a second thickness thicker than the first thickness.

12. A method for manufacturing a semiconductor device, comprising:
forming a first electrode on an insulating portion;
forming an insulating film on the first electrode;
forming an oxide semiconductor film having a first region, a second region, a third region, a fourth region, and a fifth region aligned in one direction on the insulating film; and
forming a second electrode that contacts the second region and forming a third electrode that contacts the fourth region,
an oxygen concentration in the second region being less than each of an oxygen concentration in the first region, an oxygen concentration in the third region, and an oxygen concentration in the fifth region, and
an oxygen concentration in the fourth region being less than each of the oxygen concentration in the first region, the oxygen concentration in the third region, and the oxygen concentration in the fifth region.

13. The method according to claim 12, wherein the forming of the oxide semiconductor film includes:
forming an oxide material film on the insulating film;
forming a protective film on the oxide material film;
forming an opening extending to the oxide material film in the protective film; and
forming the third region by implanting oxygen ions in a portion of the oxide material film via the opening.

14. The method according to claim 12, wherein the forming of the oxide semiconductor film includes:
forming an oxide material film on the insulating film;
forming a protective film on the oxide material film;
forming an opening extending to the oxide material film in the protective film; and
forming the third region by increasing the oxygen concentration in a portion of the oxide material film via the opening by annealing in an oxygen atmosphere.

15. The method according to claim 12, wherein the forming of the oxide semiconductor film includes:
forming an oxide material film on the insulating film;
forming a protective film on the oxide material film;
forming a first opening and a second opening extending to the oxide material film in the protective film;
forming a first metal portion that contacts the oxide material film in the first opening and forming a second metal portion that contacts the oxide material film in the second opening; and
forming the second region using oxygen reduction in a region of a first portion of the oxide material film through the first metal portion, and forming the fourth region using oxygen reduction in a region of a second portion of the oxide material film through the second metal portion.

16. The method according to claim 15, wherein the first metal portion includes a plurality of granular metals, and
the second metal portion includes a plurality of granular metals.
